(19) United States
(12) Patent Application Publication
(10) Pub. No.: US 2026/0236067 A1
(43) Pub. Date: Aug. 13, 2026

(54) DISPLAY MODULE, METHOD FOR PREPARING DISPLAY MODULE AND DISPLAY DEVICE

(71) Applicant: Xiamen Tianma Display Technology Co., Ltd., Xiamen (CN)

(72) Inventors: Zhiwei WANG, XIamen (CN); Liqin WEN, Xiamen (CN)

(73) Assignee: Xiamen Tianma Display Technology Co., Ltd., Xiamen (CN)

(21) Appl. No.: 19/232,815

(22) Filed: Jun. 9, 2025

(30) Foreign Application Priority Data
Feb. 8, 2025 (CN) 202510142035.7

(51) Int. Cl. G06F 1/16

(52) U.S. Cl. CPC G06F 1/1637; G06F 1/1658

(57) ABSTRACT

Embodiments of the present application provide a display module, a method for preparing a display module and a display device. The display module comprises: a display panel comprising a display portion, a bending portion and a connecting portion, the bending portion connects the display portion and the connecting portion; a cover plate assembly comprising a cover body and a fixing portion participating in defining a first accommodating space; a circuit board assembly electrically connected to the connecting portion; a protective assembly comprising a first protective structure at least on one side of the bending portion, and a second protective structure covering the first protective structure, a part of the second protective structure extends and fills the first accommodating space, a part of the second protective structure extends to the position of the connecting portion.

### CROSS-REFERENCE TO RELATED APPLICATION

The present application claims priority to Chinese Patent Application No. 202510142035.7 filed on February 8, 2025, and titled “DISPLAY MODULE, METHOD FOR PREPARING DISPLAY MODULE AND DISPLAY DEVICE”, which is incorporated herein by reference in its entirety.

### TECHNICAL FIELD

The present application relates to the technical field of display, in particular to a display module, a method for preparing the display module, and a display device.

### BACKGROUND

With the development of display technology, people have higher and higher requirements for narrow bezel screens. As a large number of circuits and cables are integrated at the lower bezel of the screen, it is the most difficult to narrow the lower bezel. In the prior art, a part of the display panel at the lower bezel position needs to be bent 180 ° toward the backlight side, and the bending of the display panel will produce a semicircular arc structure. In order to improve the mechanical properties and electrical protective properties at the position of the semicircular arc structure, a thin layer of protective adhesive is generally applied on the surface of the display panel. However, due to the limited thickness of the protective adhesive, there are still problems that the protective adhesive layer falls off in the subsequent extrusion test, and the position of the semicircular arc structure is damaged by the static electricity released by the electrostatic discharge circuit in the electrostatic test.

### SUMMARY

Embodiments of the present application provide a display module, a method for preparing the display module, and a display device, which can effectively enhance mechanical properties and electrical protection properties at a position of a bending portion.

According to a first aspect, embodiments of the present application provide a display module comprising a backplate assembly, a display panel, a cover plate assembly, a circuit board assembly, and a protective assembly, the backplate assembly comprises a first surface and a second surface oppositely arranged in a thickness direction; the display panel comprises a display portion, a bending portion and a connecting portion, the display portion is provided on the first surface, the connecting portion is provided on the second surface, and the bending portion connects the display portion and the connecting portion; the cover plate assembly is arranged on a side of the first surface, the cover plate assembly comprises a cover body and a fixing portion attached to a side of the cover body, the cover body, the fixing portion, the display portion and the bending portion participate in defining the first accommodating space; the circuit board assembly is arranged on a side of the second surface and electrically connected with the connecting portion; the protective assembly comprises a first protective structure and a second protective structure, the first protective structure is located at least on one side of the bending portion away from the backplate assembly, the second protective structure covers the first protective structure, a part of the second protective structure extends and fills the first accommodating space, and a part of the second protective structure extends to the position of the connecting portion.

According to a second aspect, based on the same inventive concept, embodiments of the present application provide a method for preparing a display module, comprising:

providing a prefabricated module, the prefabricated module comprises a backplate assembly, a display panel and a first protective structure, the display panel comprises a display portion, a bending portion and a connecting portion, the backplate assembly comprises a first surface and a second surface oppositely arranged in a thickness direction, the first protective structure covers a side of the display panel away from the backplate assembly, the display portion is arranged on the first surface, the connecting portion is arranged on the second surface, and the bending portion is bent to connect the display portion and the connecting portion on a side of the backplate assembly;

forming a cover plate assembly on a side of the first surface, the cover plate assembly comprises a cover body and a fixing portion, the fixing portion and the cover body are sequentially attached to a side of the first surface, and the cover body, the fixing portion, the display portion and the bending portion participate in defining the first accommodating space;

forming a circuit board assembly electrically connected to the connecting portion on a side of the second surface, the circuit board assembly comprises a circuit board and a binding member, the binding member comprises a binding strap and a limiter, the circuit board assembly is arranged on a side of the second surface, the binding strap crosses the circuit board and is attached to two opposite sides of the circuit board, the binding strap is arranged on a side of the backplate assembly beyond the backplate assembly, the binding strap, the connecting portion and the bending portion participate in defining the second accommodating space; and/or, the binding strap is attached to the limiter, a part of the limiter is arranged on a side of the backplate assembly beyond the backplate assembly, the limiter, the connecting portion and the bending portion participate in defining the second accommodating space.

forming a second protective structure in the first accommodating space, on the first protective structure and in the second accommodating space, the second protective structure partially filled in the second accommodating space and extends to the position of the connecting portion.

According to a third aspect, based on the same inventive concept, embodiments of the present application provides a display device comprising the display module provided by any one of the embodiments of the first aspect of the present application, or comprising a display module prepared by a method for preparing the display module provided by any one of the embodiments of the second aspect of the present application.

### BRIEF DESCRIPTION OF THE DRAWINGS

Features, advantages, and technical effects of exemplary embodiments of the present application will be described below with reference to the accompanying drawings.

FIG. 1 is a schematic view of an overall structure and a cross-sectional structure along an A-A direction of a display panel according to the related art;

FIG. 2 is a schematic view of an overall structure and a cross-sectional structure along the B-B direction of another display panel provided by the related art;

FIG. 3 is a schematic diagram of an overall structure of the display panel according to an embodiment of the first aspect of the present application;

FIG. 4 is a schematic cross-sectional view of FIG. 3 along the C-C direction;

FIG. 5 is another schematic cross-sectional view of FIG. 3 along the C-C direction;

FIG. 6 is a schematic diagram of an overall structure of a display panel provided by another embodiment of the first aspect of the present application;

FIG. 7A is another cross-sectional schematic view of FIG. 6 in the D-D direction;

FIG. 7B is another cross-sectional schematic view of FIG. 6 in the D-D direction;

FIG. 8 is another schematic cross-sectional view of FIG. 3 along the C-C direction;

FIG. 9 is another schematic cross-sectional view of FIG. 7 along the C-C direction;

FIG. 10 is another schematic cross-sectional view of FIG. 7 along the C-C direction;

FIG. 11 is an enlarged schematic view of the structure of E area in FIG. 4;

FIG. 12 is another enlarged schematic diagram of the E area in FIG. 4;

FIG. 13 is a flowchart of steps of a method for preparing a display module according to an embodiment of the second aspect of the present application;

FIG. 14 is a step flowchart of a method for preparing a display module according to another embodiment of the second aspect of the present application;

FIG. 15 is a step flowchart of a method for preparing a display module according to another embodiment of the second aspect of the present application;

FIG. 16 is a step flowchart of a method for preparing a display module according to another embodiment of the second aspect of the present application;

FIGS. 17A to 17E are process step diagrams of a method for preparing a display module according to an embodiment of the second aspect of the present application;

FIGS. 18A to 18F are process step diagrams of a method for preparing a display module according to another embodiment of the second aspect of the present application;

FIGS. 19A to 19F are process step diagrams of a method for preparing a display module according to another embodiment of the second aspect of the present application;

FIGS. 20A to 20F are process step diagrams of a method for preparing a display module according to another embodiment of the second aspect of the present application;

FIGS. 21A to 21D are process step diagrams of a method for preparing a display module according to another embodiment of the second aspect of the present application;

FIGS. 22A to 22D are process step diagrams of a method for preparing a display module according to another embodiment of the second aspect of the present application;

FIG. 23 is an overall structural diagram of a display device according to an embodiment of the third aspect of the present application.

### Reference numerals:

100-display module; 100'-prefabricated module;

10-backplate assembly; 10a-first surface; 10b-second surface; 10c-first side surface; 10d-second side surface;

20-display panel; 21-display portion; 22-bending portion; 23-connecting portion; 24-polarizer layer;

30-cover plate assembly; 31-cover body; 32 fixing portion;

40-circuit board assembly; 41-circuit board; 42-binding member; 42a-binding strap 42b-limiter; 421-first spacer portion; 422 second spacer portion; 423-stiffening section; 424 support portion; 425 first limit portion; 426 second limit portion;

50-protection assembly; 51- first protective structure; 52- second protective structure;

S1-first accommodating space; S2- second accommodating space;

D1- first preset distance; D2- second preset distance; D3- third preset distance;

Z-thickness direction; H-plane direction;

200-display device

In the drawings, same reference numerals are used for same components. The drawings are not drawn to actual scale.

### DETAILED DESCRIPTION

Features and exemplary embodiments of various aspects of the present application will be described in detail below. In the detailed description below, many specific details are proposed to provide a comprehensive understanding of the present application. However, it is obvious to those skilled in the art that the present application can be implemented without the need for some of these specific details. The following description of the embodiments is only intended to provide a better understanding of the present application by illustrating examples of the present application. In the accompanying drawings and the following description, at least part of the known structures and technologies are not shown to avoid unnecessary ambiguity in the present application; and, for clarity, the size of some structures may be exaggerated. In addition, features, structures or characteristics described below may be combined in one or more embodiments in any suitable manner.

The location words appearing in the following description are the directions shown in the drawings, and do not limit the specific configuration of the display module and the display device of the present application. In the description of the present application, it should also be noted that unless otherwise explicitly specified and defined, the terms "mounted" and "connected" should be understood in a broad sense, for example, they may be fixed connected, detachable connected, or integrally connected; it can be directly connected or indirectly connected. The specific meaning of the above terms in the present application will be understood by those of ordinary skilled in the art as the case may be.

It will be apparent to those skilled in the art that various modifications and variations can be made in the application without departing from the gist or scope of the application. Accordingly, the present application is intended to cover modifications and variations of the present application that fall within the scope of the corresponding claims (claimed technical solutions) and their equivalents. It should be noted that embodiments of the present application may be combined with each other unless there is no contradiction.

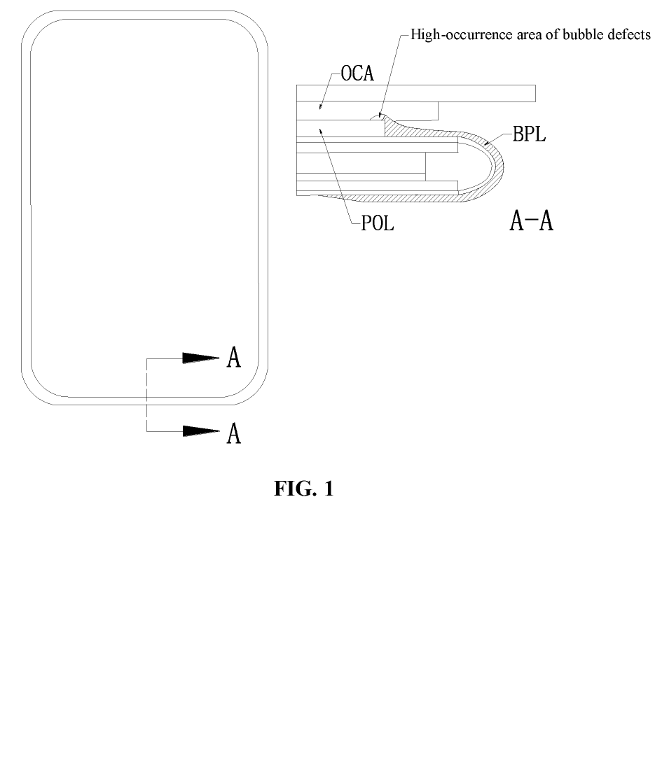

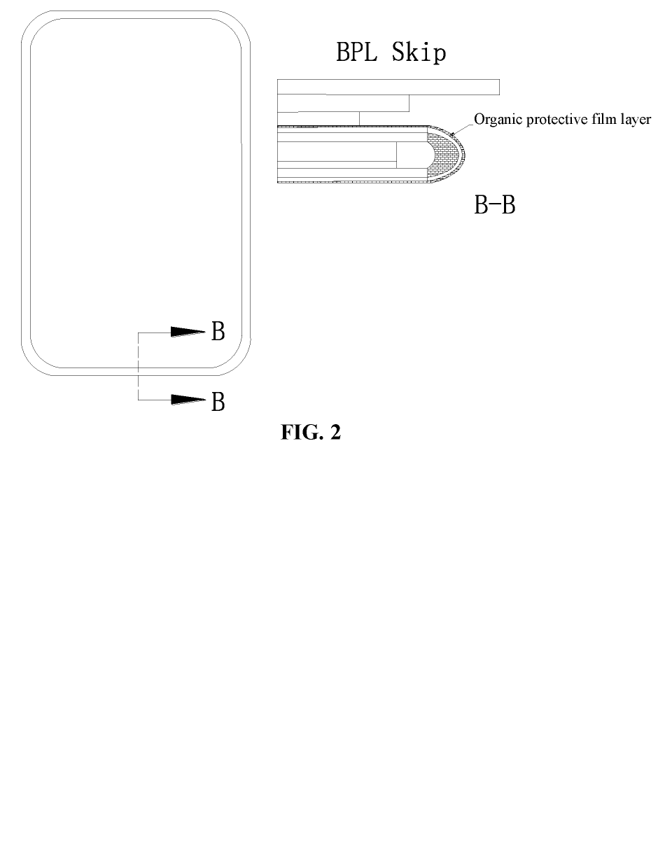

FIG. 1 shows an overall structure and a cross-sectional structure along the A-A direction of a display panel according to the related art, and FIG. 2 shows an overall structure and a cross-sectional structure along the B-B direction of another display panel according to the related art.

In related technologies, in order to meet the increasing requirements for full-screen development, industry processes have gradually developed extremely narrow bezels, in which narrowing the bezel of the lower bezel is the core process. Since a large number of circuit traces are integrated at the lower bezel position and cables that extend out of the screen to connect to control chips (Integrated Circuit, IC), it is most difficult to narrow the lower bezel. In the related art, the Chip On Panel process (COP) has recently been developed.

The COP process requires that part of the screen near the lower bezel position for non-display functions be bent 180 ° to the backlight side of the screen, and the display panel is bent at the lower bezel position to produce a semicircular arc structure. As the structure at the bending position is fragile, the semicircular arc structure at the bending position has poor reliability in mechanical extrusion test and electrostatic test during bending and after bending.

Referring to FIG. 1, a solution in the related art is to first apply a Border Protective Layer (BPL) near the bending position of the display panel. The Border Protective Layer can fulfill the functions of dustproof, waterproof and oil-proof, while it can further improve the reliability of the screen bending here, and further improve the mechanical extrusion resistance and electrical protection performance in the mechanical extrusion test and electrostatic test after subsequent bending.

However, in the BPL solution, it is difficult in the current adhesive coating process to apply the Border Protective Layer at the bending position on the Polarizer side of the screen with the thickness of BPL not exceeding the thickness of the Polarizer (POL).

In the existing adhesive coating process, BPL will overflow to the surface of POL. When the cover plate assembly is attached to the POL surface in the subsequent process, the part of BPL that overflows to the POL surface will come into contact with the Optically Clear Adhesive (OCA) used for bonding and partly swell in the OCA to cause gas entrapment problems, resulting in frequent bubble defects in the OCA, which affects the performance of the final product.

Please refer to FIG. 2. In order to solve the problems existing in the above solution, eliminate the frequent bubble defects resulting from the BPL solution and further protect the semicircular arc structure at the bending position, the industry has further developed a solution of skipping the BPL (BPL Skip) by canceling the BPL, but directly attaching a thinner organic protective film layer above the screen, and filling the cavity of the semicircular arc structure formed at the bending position with inner sealing adhesive.

The organic protective film layer is provided with a clearance area on the light-emitting side of the screen, so that the arrangement of the organic protective film layer does not affect the light-emitting effect of the screen, and the organic protective film layer is attached to other areas of the screen, so that the arrangement of the organic protective film layer and the inner sealing adhesive can also improve the reliability of the screen bending here, and further improve the mechanical extrusion resistance and electrical protection performance in the mechanical extrusion test and electrostatic test after subsequent bending.

However, under the limitation of the stacking thickness of the entire display module, the thickness of the organic protective film layer used in the BPL Skip solution is limited and generally set within 3μm. Under the premise that the thickness of the organic protective film layer is thin, the modulus of the organic protective film layer is less than 10MPa, while the modulus of the border protective adhesive in the BPL solution after curing is not less than 210MPa. Compared with the border protective adhesive in the BPL solution, the organic protective film layer in the BPL Skip solution is relatively fragile.

Therefore, as the organic protective film layer is relatively fragile, there is a performance problem that the organic protective film layer is easy to break and fall off in the subsequent bezel crush test; at the same time, as the organic protective film layer is thin, there is a performance problem that it is easily broken down by the static electricity released by the electrostatic discharge circuit in the electrostatic test, which leads to the problem that the electrical components of the semicircular arc structure at the bending position are broken down by electrostatic electricity. The BPL Skip solution still has the problems of poor reliability in mechanical extrusion test and in the electrostatic test after subsequent bending.

In order to further solve the above-described technical problems and technical considerations, embodiments of the present application provide a display module, a method for preparing the display module, and a display device.

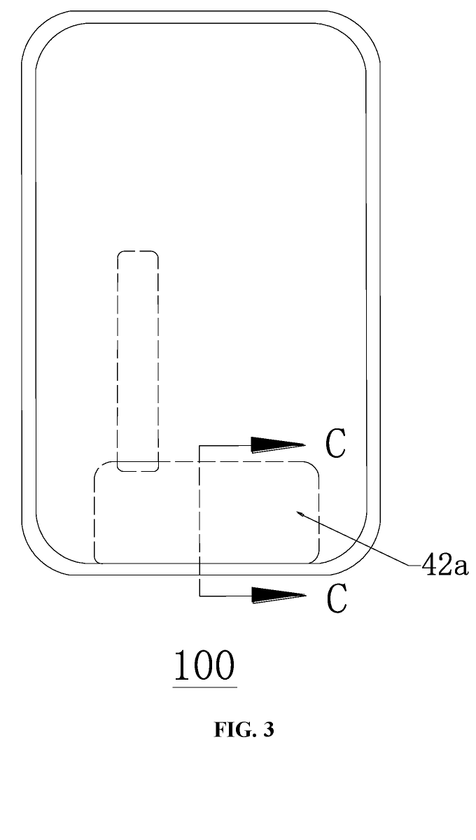

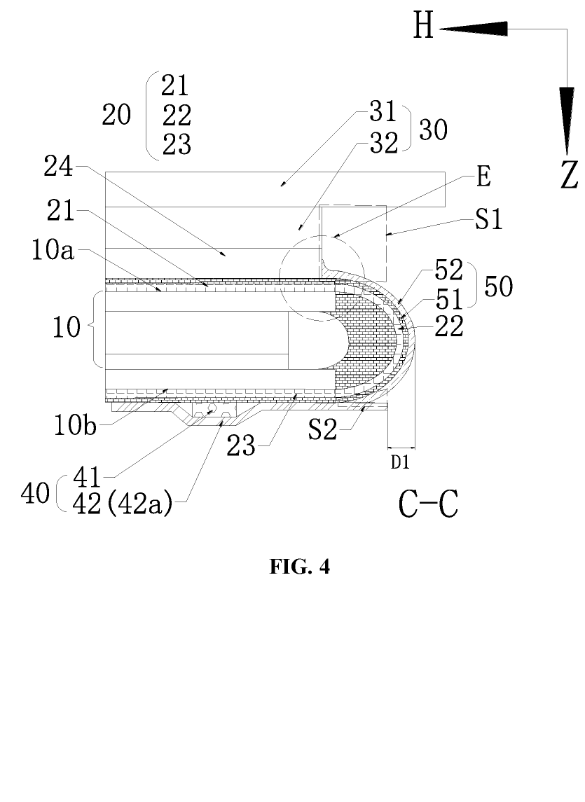

FIG. 3 shows the overall structure of the display panel 20 provided by an embodiment of the first aspect of the present application, and FIG. 4 shows a cross-sectional structure along the C-C direction in FIG. 3.

Referring to FIGS. 3 and 4, according to the first aspect, an embodiment of the present application provides a display module 100, which comprises a backplate assembly 10, a display panel 20, a cover plate assembly 30, a circuit board assembly 40, and a protective assembly 50.

The backplate assembly 10 comprises a first surface 10a and a second surface 10b oppositely arranged in the thickness direction Z.

The display panel 20 comprises a display portion 21 provided on the first surface 10a, a bending portion 22 provided on the second surface 10b, and a connecting portion 23, and the bending portion 22 connects the display portion 21 and the connecting portion 23.

The cover plate assembly 30 is provided on a side of the first surface 10a, the cover plate assembly 30 comprises a cover body 31 and a fixing portion 32 attached to a side of the cover body 31, and the cover body 31, the fixing portion 32, the display portion 21, and the bending portion 22 participate in defining a first accommodating space S1.

The circuit board assembly 40 is provided on a side of the second surface 10b and is electrically connected to the connecting portion 23.

The protective assembly 50 comprises a first protective structure 51 and a second protective structure 52, the first protective structure 51 is located at least on one side of the bending portion 22 away from the backplate assembly 10, the second protective structure 52 covers the first protective structure 51, a part of the second protective structure 52 extends and fills the first accommodating space S1, and a part of the second protective structure 52 extends to the position of the connecting portion 23.

In the first aspect, in the display module 100 provided by the embodiments of the present application, the second protective structure 52 is further provided at the position of the bending portion 22 on the basis of the first protective structure 51, so that the mechanical properties and electrical protective properties at the position of the bending portion 22 are enhanced, and the size of the second protective structure 52 is limited by the existing structure of the display module 100, the shape of the second protective structure 52 can be flexibly adjusted, and the error value within the allowable range of the process is increased, which is beneficial to reduce the difficulty and cost of forming the second protective structure 52.

The backplate assembly 10 may be provided in various ways. The backplate assembly 10 may comprise a Super Clean Foam (SCF) layer, a plurality of backplates arranged on both sides of the SCF layer, and a support layer. The SCF layer is mainly composed of a three-layer structure of foam, graphite and copper foil. The SCF layer mainly fulfills the functions of support, load-bearing and impact resistance. Other film layers such as the support layer and the backplate are sequentially stacked on the substrate. The arrangement of “being stacked” mentioned here means that other film layers are sequentially arranged along the thickness direction Z of the substrate.

The SCF layer may further comprise a plurality of film layer structures, and the specific film layer structure composition in the SCF layer is not limited in the embodiments of the present application.

Since the display panel 20, the cover plate assembly 30, and the circuit board assembly 40 are all provided on a side of the first surface 10a or the second surface 10b, and the backplate assembly 10 is provided with the first surface 10a and the second surface 10b provided oppositely in the thickness direction Z, the thickness direction Z of the display panel 20, the cover plate assembly 30, and the circuit board assembly 40 is the same as the thickness direction Z of the backplate assembly 10, and the display panel 20, the cover plate assembly 30, and the circuit board assembly 40 are also provided in the thickness direction Z.

The thickness direction Z of other film layers such as the support layer and the backplate located on a side of the SCF layer is usually consistent with the thickness direction Z of the SCF layer itself, and the thickness direction Z of the display panel 20, the cover plate assembly 30, and the circuit board assembly 40 provided on the backplate assembly 10 is also consistent with the thickness direction Z of the SCF layer itself. Therefore, for convenience of expression, the thickness directions Z of other different film layers mentioned later in the embodiments of the present application are all in the same direction.

The display panel 20 is a functional device that fulfills a main display function in the display module 100, which is on a side of the backplate assembly 10, for example, at a lower bezel position, the connecting portion 23 of the display panel 20 is bent to the second surface 10b of the backplate assembly 10, the bending portion 22 connects the display portion 21 located on the first surface 10a and the connecting portion 23 located on the second surface 10b, and the bending portion 22 may form a semicircular arc structure on a side of the backplate assembly 10.

For example, the cover plate body 31 in the cover plate assembly 30 usually comprises a protective film layer as the outermost cover layer and Ultra Thin Glass (UTG) arranged to be retracted inwardly from the edges of the protective film layer. The inwardly retracted arrangement of the UTG contributes to avoiding the risk that the edge of the UTG is easily cracked due to too thin thickness. The fixing portion 32 serves as a structure for fixedly connecting the cover body 31 and the display panel 20. The size of the fixing portion 32 is adapted to that of the UTG. Therefore, when the cover plate assembly 30 is arranged on a side of the first surface 10a, the cover body 31, the fixing portion 32, and the bending portion 22 participate in defining the first accommodation space S1.

Exemplarily, the fixing portion 32 is an optical clear adhesive (OCA)adhesive.

Exemplarily, since the display panel 20 is further provided with the polarizer layer 24 above the display portion 21 on the side of the first surface 10a, the cover body 31, the fixed portion 32, the polarizer layer 24, and the bending portion 22 can further participate in defining the first accommodating space S1.

Exemplarily, the cover plate assembly 30 is provided on a side of the first surface 10a, and the cover body 31 of the cover plate assembly 30 is provided on a side of the display panel 20 provided with the bending portion 22, exemplarily beyond the backplate assembly 10 at the lower bezel position, so that the first accommodating space S1 in which the cover body 31 and the bending portion 22 on two sides are protruded and the fixing portion 32 is recessed is formed on a side of the backplate assembly 10.

The first accommodating space S1 is more obvious because the cover body 31 is provided on the side of the backplate assembly 10 beyond the backplate assembly 10. In fact, the positional relationship between the cover body 31 and the backplate assembly 10 on the side of the backplate assembly 10 is not limited in the embodiments of the first aspect of the present application. The cover plate body 31 may extend beyond the backplate assembly 10 on a side of the backplate assembly 10, may be flush with the backplate assembly 10 on a side of the backplate assembly 10, or may be retracted inwardly from the backplate assembly 10 on a side of the backplate assembly 10.

The main function of the circuit board assembly 40 is to control the light-emitting function of the display panel 20, and after the circuit board assembly 40 is electrically connected to the connecting portion 23 bent to the side of the second surface 10b, the light-emitting function of the light-emitting device in the display portion 21 on a side of the first surface 10a can be controlled, and different instructions can be transmitted to realize the required light-emitting function. It should be noted that, the display portion comprises a display area and a non-display area.

In addition to the first protective structure 51 located at least on one side of the bending portion 22 before the bending portion 22 is bent to form the semicircular arc structure, the protective assembly 50 is further provided with a second protective structure 52 at the position of the bending portion 22 that forms the semicircular arc structure after bending, so as to further enhance the mechanical properties and electrical protective properties at the position of the bending portion 22.

For example, the first protective structure 51 is an organic protective film layer, and since the thickness of the first protective structure 51 is relatively thin, there is a low risk of the thickness of the first protective structure 51 exceeding that of the polarizer layer 24 when the organic protective film layer is applied at the position of the bending portion 22 before bending. The first protective structure 51 can effectively protect the bending portion 22 during bending while also preventing gas entrapment between the fixing portion 32 and the polarizer layer 24 after the cover plate assembly 30 is installed, thereby reducing the risk of frequent bubble formation.

Exemplarily, the protective assembly 50 may further comprise an inner sealing adhesive provided in the inner cavity of the semicircular arc structure formed by the bending portion 22, which can protect the bending portion 22 on both opposite sides of the bending portion 22, and further effectively protect the bending portion 22 when it is bent.

The second protective structure 52 covers the first protective structure 51, it should be understood that after the display panel 20 is bent and the cover body 31 is arranged on the first surface 10a of the backplate assembly 10, the second protective structure 52 covers at least the first protective structure 51 provided at the position of the bending portion 22 to protect the bending portion 22. The arrangement of the second protective structure 52 can further protect the bending portion 22, the problem of poor reliability in subsequent tests caused by the thin thickness and fragileness of the first protective structure 51 on the side of the bending portion 22 has a low risk of occurrence after the arrangement of the second protective structure 52.

Furthermore, the boundary and shape and size of the second protective structure 52 can be realized by the first accommodating space S1 and other partial structures formed by the existing structure, the second protective structure 52 can be limited on both sides of the first surface 10a and the second surface 10b, so that the error value range allowed in the production process can be effectively increased, and the difficulty and cost of forming the second protective structure 52 can be reduced.

In the first accommodating space S1 formed by the existing structure, part of the second protective structure 52 can only extend on a side of the first surface 10a and fill in the first accommodating space S1.

Another part of the second protective structure 52 is limited by the existing structure or a part of auxiliary structures, and can only extend to the position of the connecting portion 23 on a side of the second surface 10b. The specific arrangement of the second protective structure 52 on the side of the second surface 10b will be further described in other embodiments of the first aspect of the present application and embodiments of the second aspect of the present application.

Still referring to FIGS. 3 and 4, in some embodiments, the circuit board assembly 40 comprises a circuit board 41 and a binding member 42, the binding member 42 is arranged partially beyond the backplate assembly 10 on a side of the backplate assembly 10, the binding member 42, the connecting portion 23, and the bending portion 22 participate in defining a second accommodating space S2, and the second protective structure 52 extends and fills the second accommodating space S2.

In these embodiments, the binding member 42 forms the second accommodating space S2 on a side of the second surface 10b, so that the second protective structure 52 can only extend and fill into the second accommodating space S2 on a side of the second surface 10b, realizing the limit of the second protective structure 52 on the side of the second surface 10b when forming the second protective structure 52, further effectively increasing the allowable error value range in the production process, and reducing the difficulty and cost of forming the second protective structure 52.

Exemplarily, the circuit board 41 is a circuit board on which the control chip IC is located.

Still referring to FIGS. 3 and 4, in some embodiments, the binding member 42 comprises a binding strap 42a attached to a side of the circuit board 41 away from the second surface 10b, and the binding strap 42a extends beyond two opposite sides of the circuit board 41 to be bound and fixed to the connecting portion 23. The binding strap 42a is arranged on a side of the backplate assembly 10 partially beyond the backplate assembly 10, the binding strap 42a, the connecting portion 23, and the bending portion 22 participate in defining the second accommodating space S2, and the second protective structure 52 extends and fills the second accommodating space S2.

In these embodiments, in addition to fixing the circuit board 41, the binding strap 42a is provided on a side of the backplate assembly 10 partially beyond the backplate assembly 10, and the second accommodating space S2 can be formed by using the existing structure, further realizing the limit of the second protective structure 52 on the side of the second surface 10b when forming the second protective structure 52, further effectively increasing the allowable error value range in the production process, and reducing the difficulty and cost of forming the second protective structure 52.

Exemplarily, the binding strap 42a is an electrical adhesive tape with good insulating characteristics.

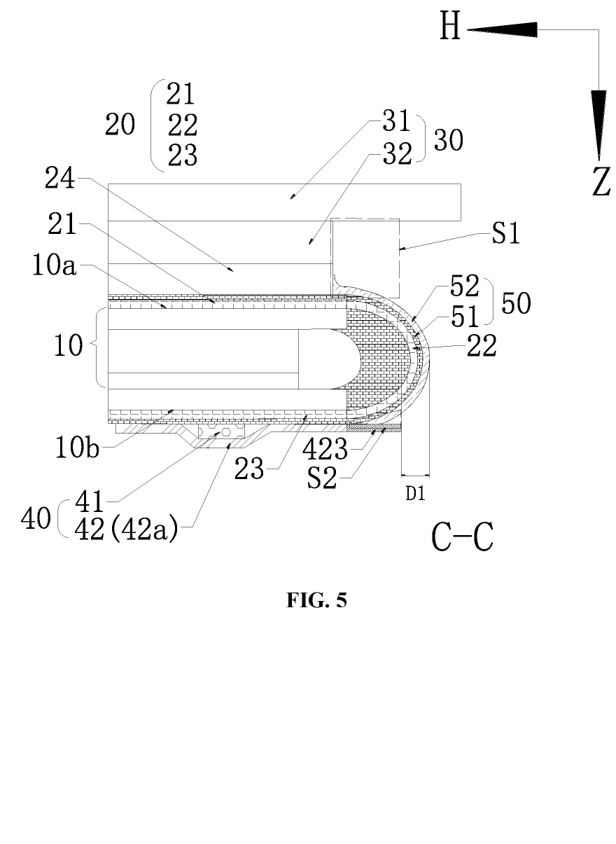

FIG. 5 shows another cross-sectional structure in FIG. 3 along the C-C direction.

Referring to FIG. 5, in some embodiments, the binding strap 42a further comprises a stiffening section 423 arranged on a side of the backplate assembly 10 beyond the backplate assembly 10, the stiffening section 423, the connecting portion 23, and the bending portion 22 participate in defining the second accommodating space S2, and the second protective structure 52 extends and fills the second accommodating space S2.

In these embodiments, the arrangement of the stiffening section 423 can more conveniently realize the formation of the second accommodating space S2 by using the structure of the binding strap 42a itself, so that the existing structure used for forming the second accommodating space S2 is not easily deformed, further realize the limit of the second protective structure 52 on the side of the second surface 10b when forming the second protective structure 52, further effectively increase the allowable error value range in the production process, and reduce the difficulty and cost of forming the second protective structure 52.

The stiffening portion 423 should be understood that, a part of the structure of the binding strap 42a close to the backplate assembly 10 has strong stiffness, an external force applied to the part of the structure of the binding strap 42a close to the backplate assembly 10 and perpendicular to the surface of the part is less likely to cause the binding strap 42a to be deflected to either side.

The arrangement of the stiffening section 423 makes the formation of the second accommodating space S2 more stable, and is more conducive to limiting the position of the second protective structure 52 on the side of the second surface 10b.

In some embodiments, the stiffening section 423 comprises a glass fiber material or a polyester fiber material, which can achieve the basic functionality of the binding strap 42a while having greater stiffness.

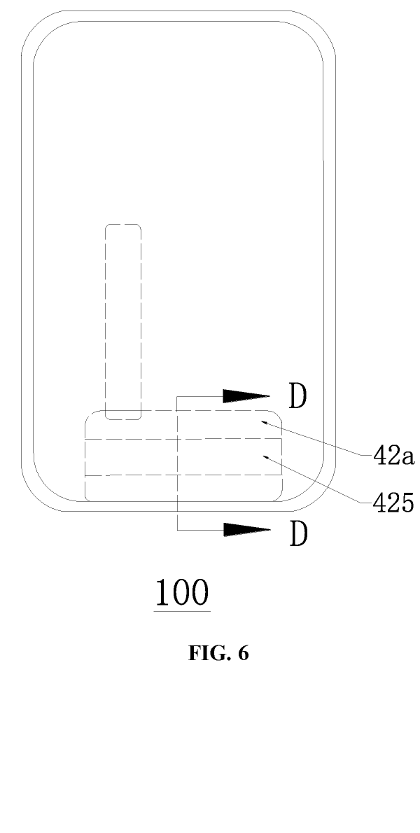

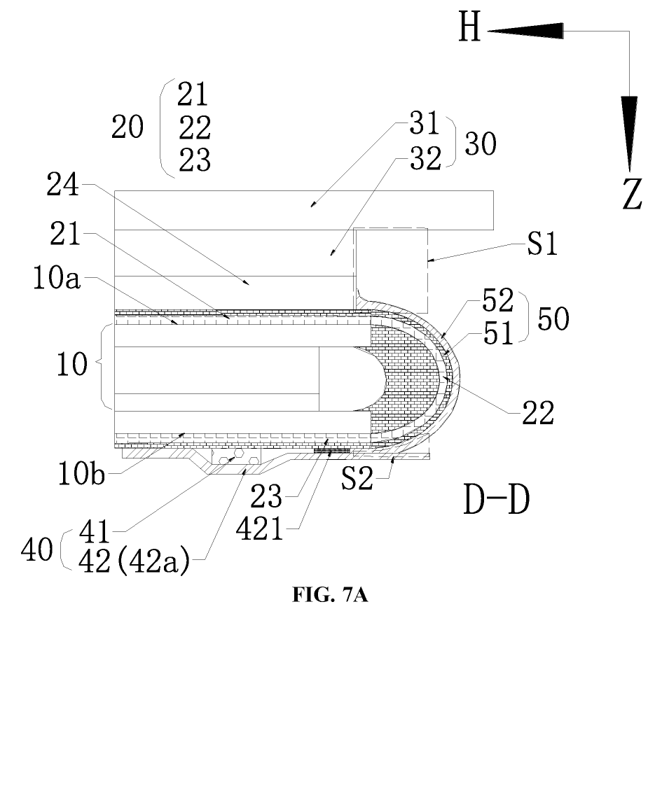

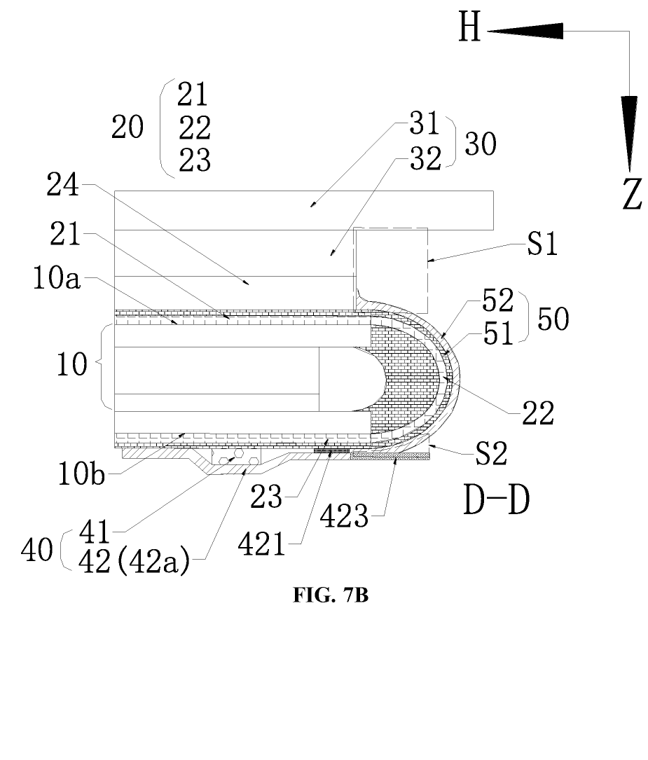

FIG. 6 shows the overall structure of a display panel 20 provided by another embodiment of the first aspect of the present application, FIG. 7A shows another cross-sectional structure along the D-D direction in FIG. 6, and FIG. 7B shows another cross-sectional structure along the D-D direction in FIG. 6.

Referring to FIGS. 6 and 7A to 7B, in some embodiments, the binding member 42 further comprises a first spacer portion 421 arranged between the stiffening section 423 and the connecting portion 23; the connecting portion 23, the stiffening section 423, the first spacer portion 421, and the bending portion 22 participate in defining the second accommodating space S2, and the second protective structure 52 extends and fills the second accommodating space S2.

Alternatively, the first spacer portion 421 is provided between the binding strap 42a and the connecting portion 23; the connecting portion 23, the binding strap 42a, the first spacer portion 421, and the bending portion 22 participate in defining the second accommodating space S2, and the second protective structure 52 extends and fills the second accommodating space S2.

In these embodiments, the arrangement of the first spacer portion 421 can further increase the effective volume of the second accommodating space S2, prevent the problem of overflow caused by excessive amount of adhesive when forming the second protective structure 52, further effectively increase the allowable error value range in the production process, and reduce the difficulty and cost of forming the second protective structure 52.

Still referring to FIGS. 7A and 7B, in some embodiments, the dimension of the first spacer portion 421 in the thickness direction Z is consistent with the dimension of an end of the second protective structure 52 extending to the second accommodating space S2 in the thickness direction Z.

In these embodiments, the arrangement of the first spacer portion 421 can control the dimension of an end of the second protective structure 52 extending inside the second accommodating space S2 on a side of the second surface 10b along the thickness direction Z, and further realize the partial size and shape control of the second protective structure 52.

In some embodiments, the first spacer portion 421 comprises a foam material, the foam material is light and elastic, has a characteristic of quick fixation by providing a pressure-sensitive adhesive, and the foam material can effectively resist electrochemical corrosion and other excellent characteristics in an environment with many electronic components.

Referring to FIGS. 4 and 5, in some embodiments, the plane direction H is a direction parallel to the plane of the backplate assembly 10, and a first preset distance D1 is set between the stiffening section 423 or the binding strap 42a and the arc top of the bending portion 22 in the plane direction H, and the plane direction H intersects with the thickness direction Z.

In these embodiments, by controlling the first preset distance D1, the distance between the stiffening section 423 or an end of the binding strap 42a and the arc top of the bending portion 22 is controlled, the effective volume of the second accommodating space S2 can be further increased, the problem of overflow caused by excessive amount of adhesive when forming the second protective structure 52 can be prevented, the allowable error value range in the production process can be further effectively increased, and the difficulty and cost of forming the second protective structure 52 can be reduced.

The plane direction H should be understood as any direction parallel to the plane in which the backplate assembly 10 is located, and therefore, the plane direction H must intersect with the thickness direction Z.

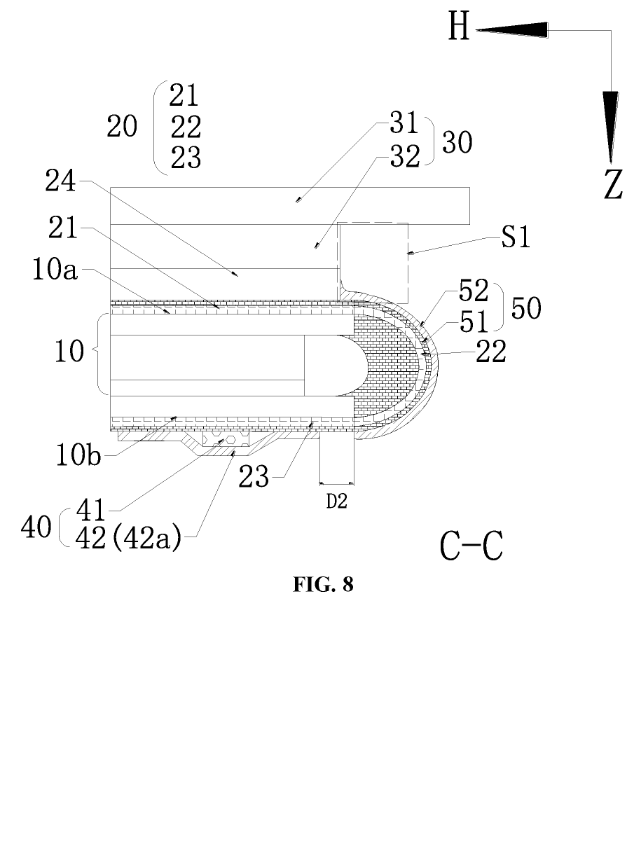

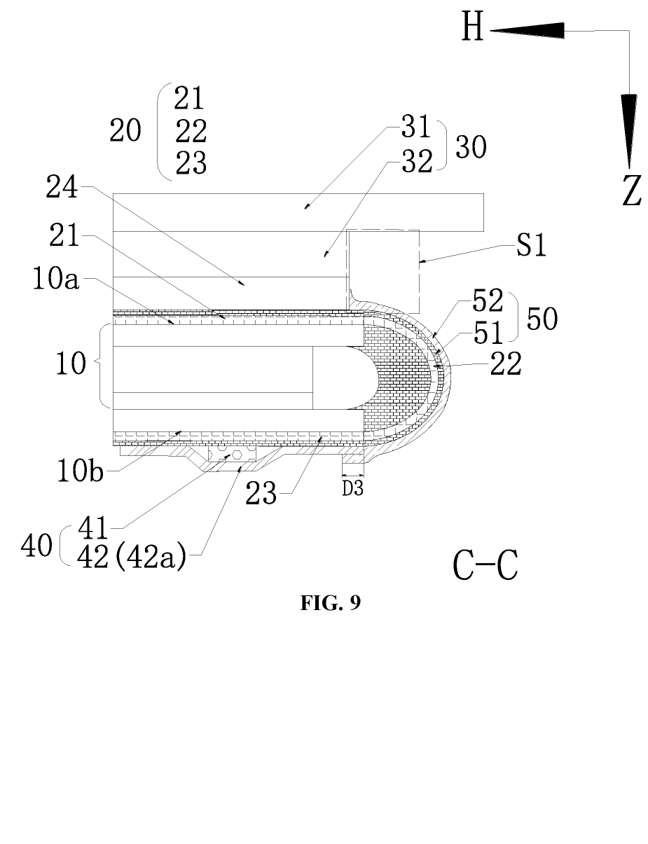

FIG. 8 shows another cross-sectional structure along the C-C direction in FIG. 3, and FIG. 9 shows another cross-sectional structure along the C-C direction in FIG. 3.

Referring to FIGS. 8 to 9, in some embodiments, the circuit board assembly 40 comprises a circuit board 41 and a binding member 42, the binding member 42 comprises a binding strap 42a attached to a side of the circuit board 41 away from the second surface 10b, and the binding strap 42a extends beyond two opposite sides of the circuit board 41 and is bound and fixed to the connecting portion 23; the plane direction H is a direction parallel to the plane of the backplate assembly 10, the second protective structure 52 extends to an end of the binding strap 42a close to the bending portion 22, a second preset distance D2 is set between the second protective structure 52 and the binding strap 52a in the plane direction H intersecting with the thickness direction.

Alternatively, the second protective structure 52 extends and covers an end of the binding strap 42a close to the bending portion 22, and the second protective structure 52 extends from an end of the binding strap 42a close to the bending portion 22 toward the connecting portion 23 for a third preset distance D3 in the plane direction H intersecting with the thickness direction Z.

In these embodiments, due to the arrangement of other auxiliary structures, the positional relationship between the extension position of the second protective structure 52 on the side of the second surface 10b and the binding strap 42a can be adjusted at any time, a second preset distance D2 can be set between the second protective structure 52 and the binding strap 42a, and the second protective structure 52 can also cover the binding strap 42a and extend by a third preset distance D3, which can be adjusted at any time according to actual needs to further realize partial size and shape control of the second protective structure 52.

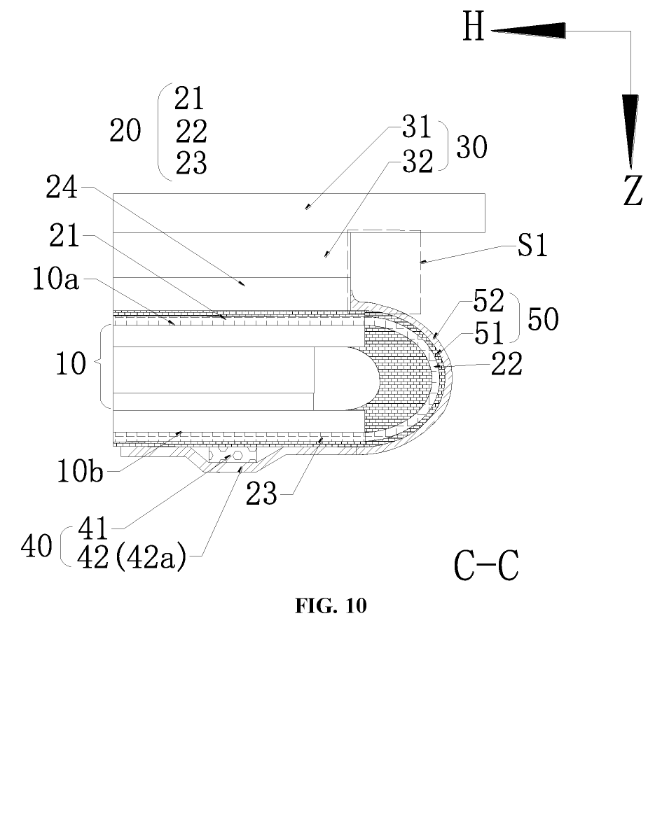

FIG. 10 shows yet another cross-sectional structure in the C-C direction of FIG. 3.

Referring to FIG. 10, in some embodiments, the second preset distance D2 or the third preset distance D3 is 0, and the second protective structure 52 abuts against the binding strap 42a.

In these embodiments, the second protective structure 52 actually abuts against the binding strap 42a, and the binding strap 42a also partially participates in limiting the second protective structure 52.

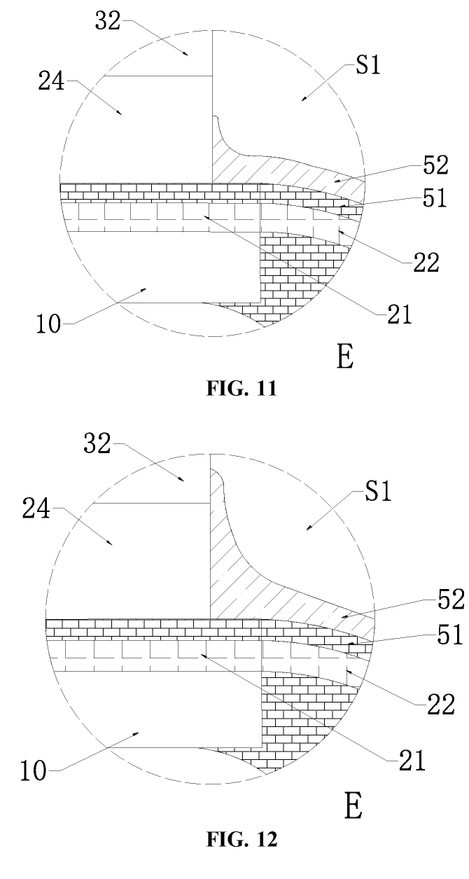

FIG. 11 shows an enlarged structure of the E area in FIG. 3.

Referring to FIG. 11, in some embodiments, the second protective structure 52 extends along the display portion 21 to a side of the fixing portion 32 close to the display portion 21 in the first accommodating space S1.

In these embodiments, the second protective structure 52 is provided in the first accommodating space S1, and can only extend along the display portion 21 to the side of the fixing portion 32 close to the display portion 21, so that the second protective structure 52 can be avoided from extending between the fixing portion 32 and the display portion 21, and the problem of gas entrapment and thus the formation of edge bubble defects can be avoided.

FIG. 12 shows another enlarged structure of the E area in FIG. 3.

Referring to FIG. 12, in some embodiments, the second protective structure 52 extends in the first accommodating space S1 and covers at least a part of side portion of the fixing portion 32.

In these embodiments, the second protective structure 52 is provided in the first accommodating space S1, and in the case that the amount of adhesive of the second protective structure 52 is too large, the second protective structure 52 can extend to and cover only the side portion of the fixing portion 32, which can further prevent the second protective structure 52 from extending between the fixing portion 32 and the display portion 21, and avoid the problem of gas entrapment and thus the formation of edge bubble defects.

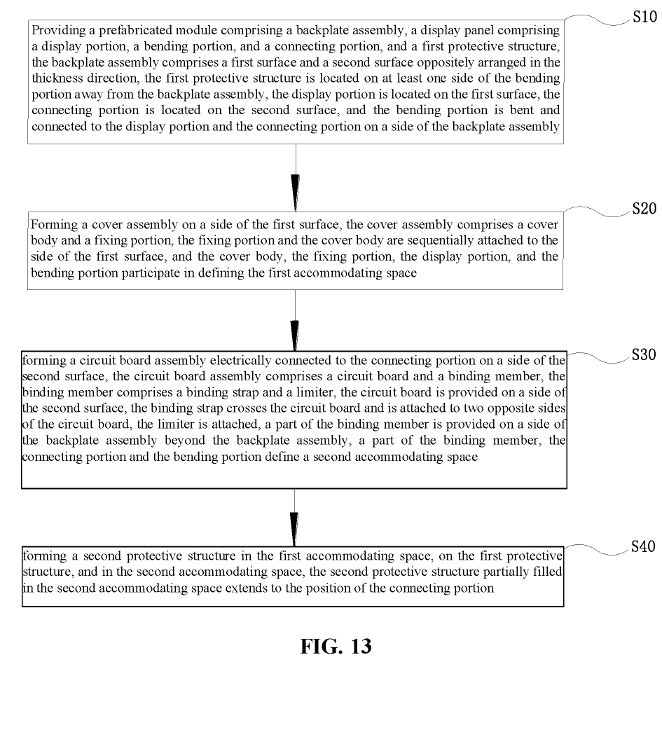

FIG. 13 shows a flow chart of a method for preparing the display module 100 according to embodiments of a second aspect of the present application.

Referring to FIG. 13, in the second aspect, embodiments of the present application provide a method for preparing a display module 100, comprising:

Step S10: providing a prefabricated module 100’ comprising a backplate assembly 10, a display panel 20 comprising a display portion 21, a bending portion 22, and a connecting portion 23, and a first protective structure 51, where the backplate assembly 10 comprises a first surface 10a and a second surface 10b oppositely arranged in the thickness direction Z, the first protective structure 51 is located on at least one side of the bending portion 22 away from the backplate assembly 10, the display portion 21 is located on the first surface 10a, the connecting portion 23 is located on the second surface 10b, and the bending portion 22 is bent on a side of the backplate assembly to connect the display portion and the connecting portion;

Step S20: forming a cover plate assembly 30 on a side of the first surface 10a, where the cover plate assembly 30 comprises a cover plate body 31 and a fixing portion 32, the fixing portion 32 and the cover plate body 31 are sequentially attached to the side of the first surface 10a, and the cover plate body 31, the fixing portion 32, the display portion 21, and the bending portion 22 participate in defining the first accommodating space S1;

Step S30: forming, on a side of the second surface 10b, a circuit board assembly 40 electrically connected to the connecting portion 23, where the circuit board assembly 40 comprises a circuit board 41 and a binding member 42, the binding member 42 comprises a binding strap 42a and a limiter 42b, the circuit board 41 is provided on a side of the second surface 10b, the binding strap 42a crosses the circuit board 41 and is attached to two opposite sides of the circuit board 41, the limiter 42b is attached, a part of the binding member 42 is provided on a side of the backplate assembly 10 beyond the backplate assembly 10, and the part of the binding member 42, the connecting portion 23, and the bending portion 22 participate in defining the second accommodating space S2; and

Step S40: forming a second protective structure 52 in the first accommodating space S1, on the first protective structure 51, and in the second accommodating space S2, where the second protective structure 52 partially filling the second accommodating space S2 extends to the position of the connecting portion 23.

In the second aspect, in the method for preparing a display module 100 provided by the embodiments of the present application, the second protective structure 52 is further formed at the position of the bending portion 22 on a side of the first protective structure 51, the mechanical properties and electrical protective properties at the position of the bending portion 22 are enhanced, while the existing structure of the display module 100 and the limiter 42b are used to form the required first accommodating space S1 and the second accommodating space S2, so as to limit the shape and size of the second protective structure 52 on the side of the first surface 10a and the side of the second surface 10b when forming the second protective structure 52. Furthermore, the cover plate assembly 30 is disposed before the formation of the second protective structure 52, which can also prevent gas entrapment so as to avoid the risk of existence of plenty of bubbles at the edges of the cover plate in final products of the display module 10.

In step S10, the prefabricated module 100' refers to an intermediate structure of the display module 100 obtained after the display panel 20 has been coated with the first protective structure 51 at the position of the bending portion 22, and the display panel 20 is partially bent at the position of the bending portion 22.

In step S30, the attached limiter 42b participates in defining the second accommodating space S2, and after the formation of the second protective structure 52, there is a step of removing a part of the limiter 42b to further narrow the stacking thickness and the bezel width of the display module 100. Relevant embodiments will be further described in other subsequent embodiments of the second aspect of the present application.

A part of the limiter 42b and the binding strap 42a can be freely combined and participate in defining the formation of the second accommodating space S2, and the embodiments of the combination between a part of the limiter 42b and the binding strap 42a will be further described in the following specific embodiments.

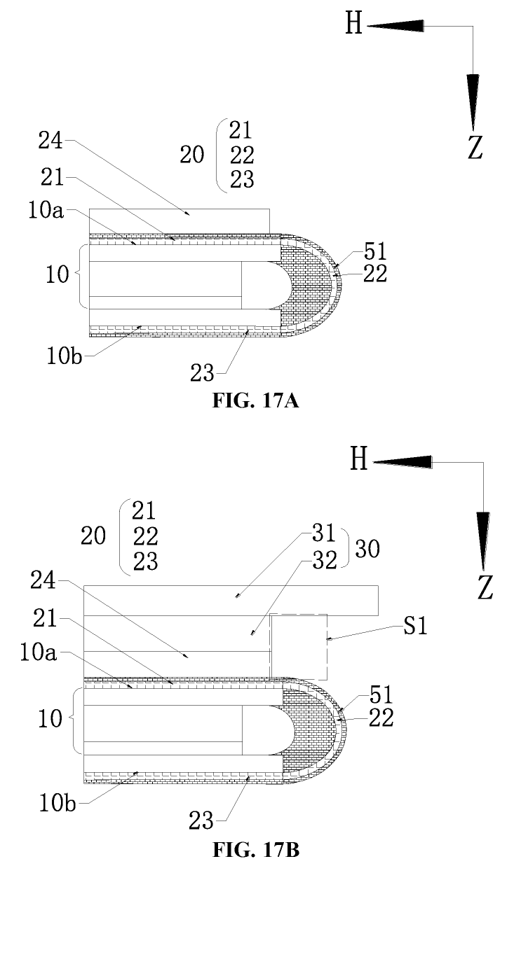

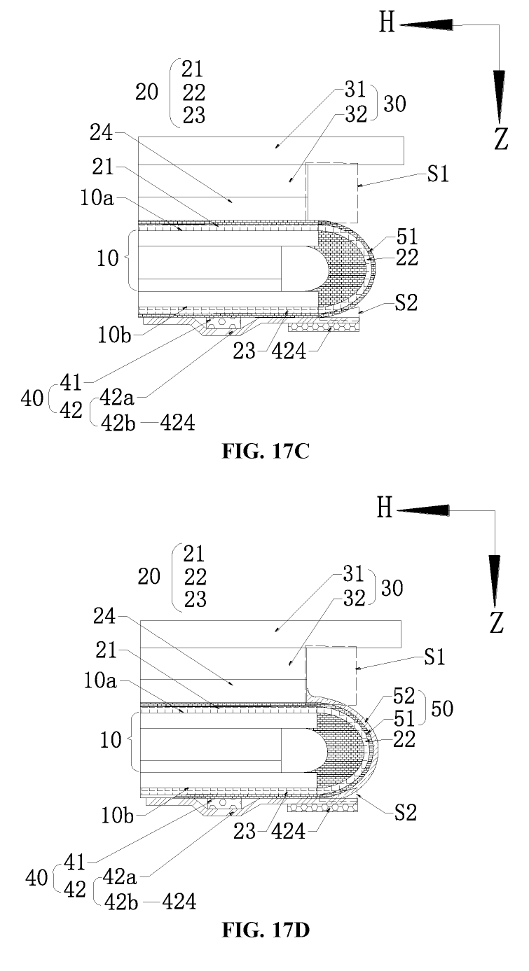

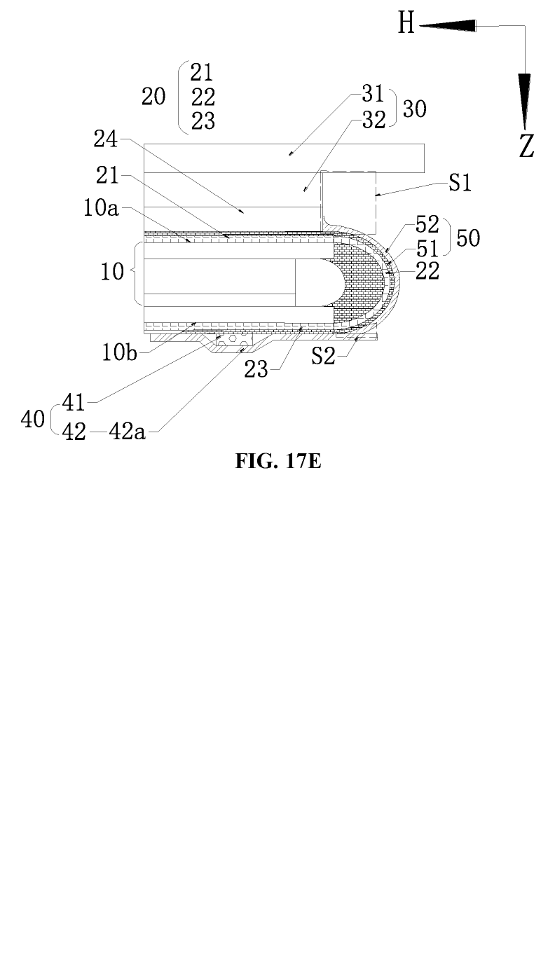

FIGS. 17A to 17E show process steps of a method for preparing a display module 100 according to an embodiment of the second aspect of the present application.

Exemplarily, a method for preparing a display module 100 according to an embodiment of the second aspect of the present application comprises:

step S10: providing the prefabricated module 100’, as shown in FIG. 17A;

step S20, forming the cover plate assembly 30 on the side of the first surface 10a, as shown in FIG. 17B;

step S30: forming, on the side of the second surface 10b, a circuit board assembly 40 electrically connected to the connecting portion 23, where the circuit board assembly 40 comprises a circuit board 41 and a binding member 42, the binding member 42 comprises a binding strap 42a and a limiter 42b, the circuit board 41 is provided on the side of the second surface 10b, the binding strap 42a crosses the circuit board 41 and is attached to two opposite sides of the circuit board 41, the limiter 42b is attached, a part of the limiter 42b and the binding strap 42a are arranged on a side of the backplate assembly 10 beyond the backplate assembly 10, and the binding strap 42a, the limiter 42b, the connecting portion 23, and the bending portion 22 participate in defining the second accommodating space S2, as shown in FIG. 17C;

step S40: forming a second protective structure 52, as shown in FIG. 17D.

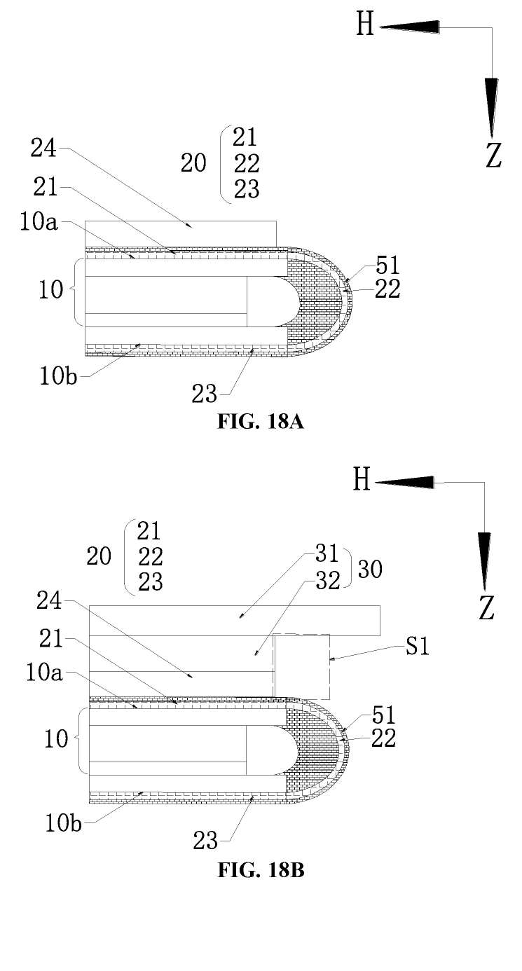

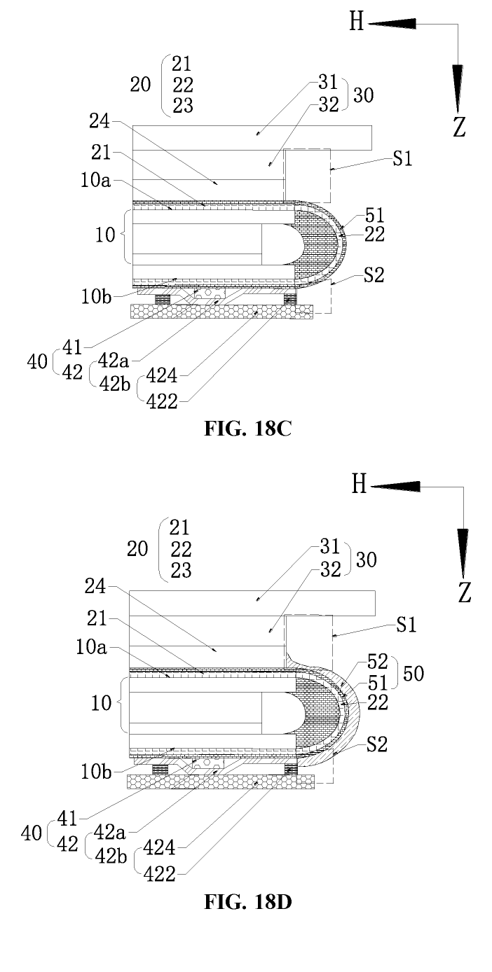

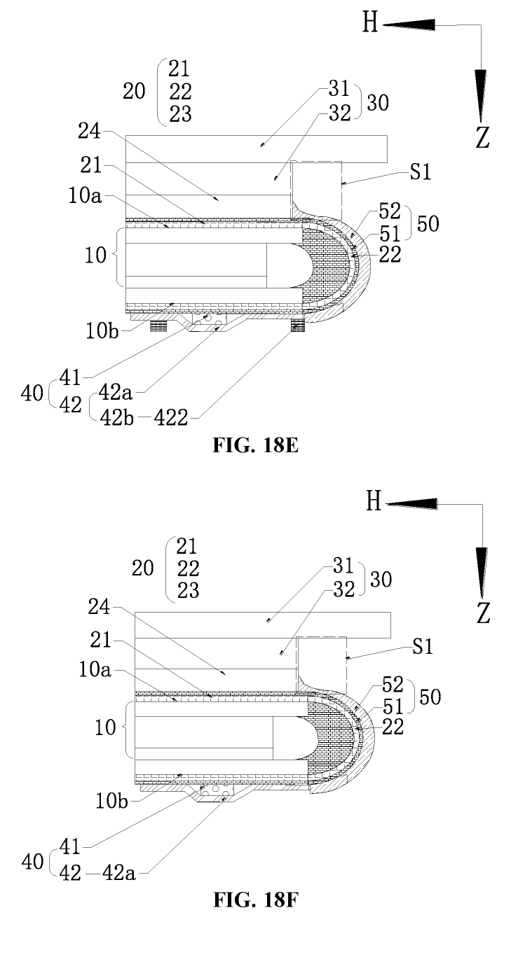

FIGS. 18A to 18F show the process steps of a method for preparing the display module 100 according to another embodiment of the second aspect of the present application.

Exemplarily, the method for preparing the display module 100 according to another embodiment of the second aspect of the present application comprises:

step S10: providing the prefabricated module 100’, as shown in FIG. 18A;

step S20: forming the cover plate assembly 30 on the side of the first surface 10a, as shown in FIG. 18B;

step S30: forming a circuit board assembly 40 electrically connected to the connecting portion 23 on the side of the second surface 10b, where the circuit board assembly 40 comprises a circuit board 41 and a binding member 42, the binding member 42 comprises a binding strap 42a and a limiter 42b, the circuit board 41 is provided on the side of the second surface 10b, the binding strap 42a crosses the circuit board 41 and is attached to two opposite sides of the circuit board 41, the limiter 42b is attached, a part of the limiter 42b is arranged on a side of the backplate assembly 10 beyond the backplate assembly 10, and the binding strap 42a, the limiter 42b, the connecting portion 23 and the bending portion 22 participate in defining the second accommodating space S2, as shown in FIG. 18C; and

step S40: forming the second protective structure 52, as shown in FIG. 18D.

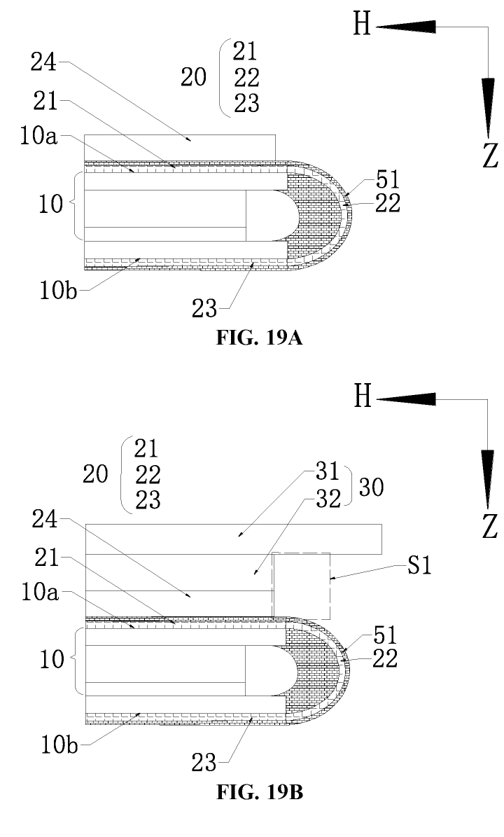

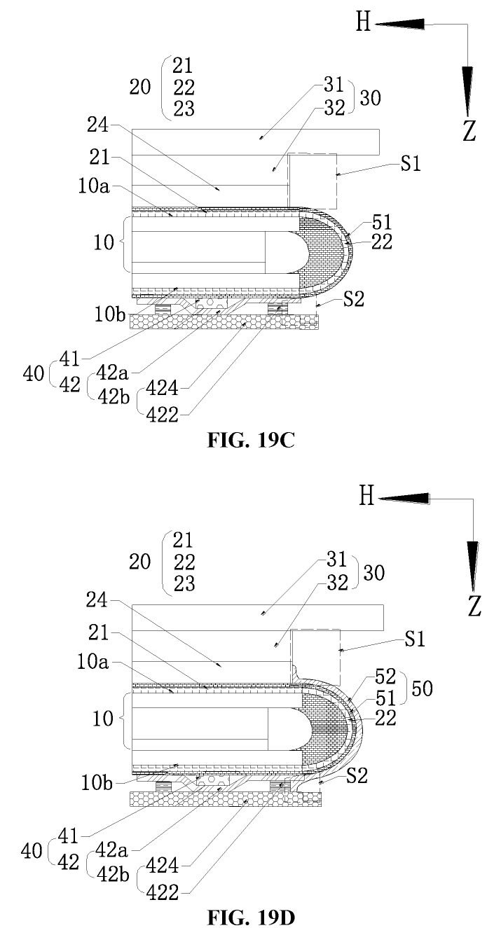

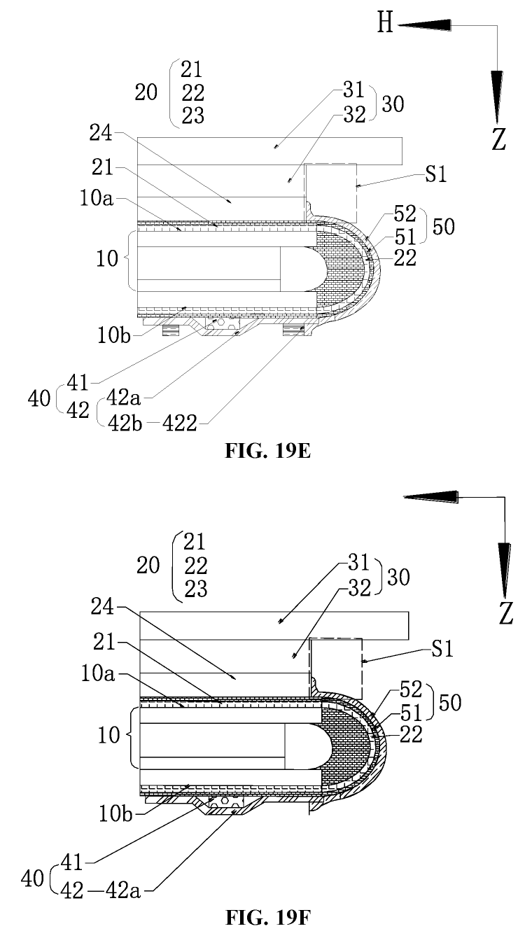

FIGS. 19A to 19F illustrate process steps of a method for preparing a display module 100 according to another embodiment of the second aspect of the present application.

Exemplarily, the method for preparing a display module 100 according to another embodiment of the second aspect of the present application comprises:

step S10: providing the prefabricated module 100’, as shown in FIG. 19A;

step S20: forming the cover plate assembly 30 on the side of the first surface 10a, as shown in FIG. 19B;

step S30: forming, on the side of the second surface 10b, the circuit board assembly 40 electrically connected to the connecting portion 23, where the circuit board assembly 40 comprises a circuit board 41 and a binding member 42, the binding member 42 comprises a binding strap 42a and a limiter 42b, the circuit board 41 is provided on the side of the second surface 10b, the binding strap 42a crosses the circuit board 41 and is attached to two opposite sides of the circuit board 41, the limiter 42b is attached, a part of the limiter 42b and the binding strap 42a are arranged on a side of the backplate assembly 10 beyond the backplate assembly 10, and the binding strap 42a, the limiter 42b, the connecting portion 23, and the bending portion 22 participate in defining the second accommodating space S2, as shown in FIG. 19C; and

step S40: forming the second protective structure 52, as shown in FIG. 19D.

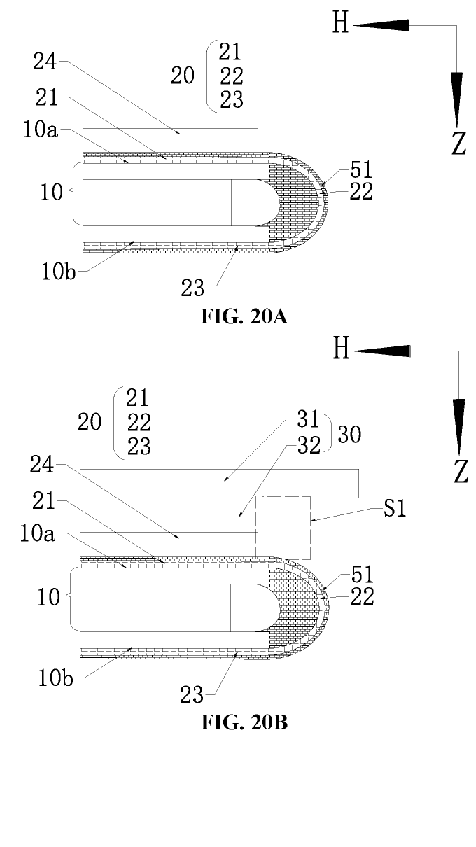

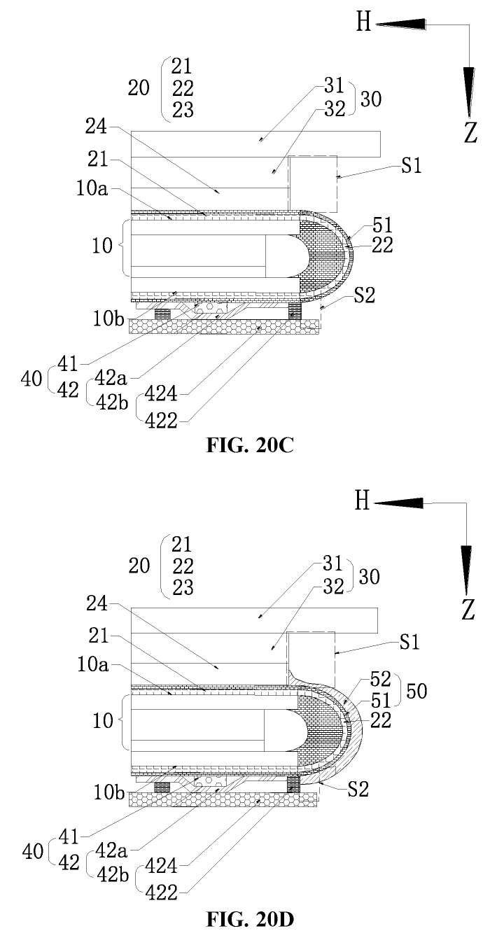

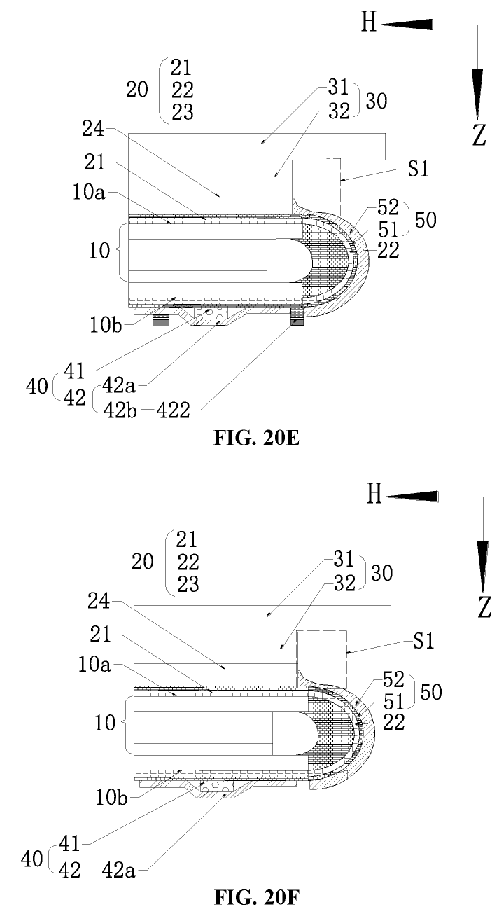

FIGS. 20A to 20F illustrate process steps of a method for preparing a display module 100 according to another embodiment of the second aspect of the present application.

Exemplarily, the method for preparing a display module 100 according to another embodiment of the second aspect of the present application comprises:

step S10: providing the prefabricated module 100’, as shown in FIG. 20A;

step S20: forming the cover plate assembly 30 on the side of the first surface 10a, as shown in FIG. 20B;

step S30: forming, on a side of the second surface 10b, a circuit board assembly 40 electrically connected to the connecting portion 23, where the circuit board assembly 40 comprises a circuit board 41 and a binding member 42, the binding member 42 comprises a binding strap 42a and a limiter 42b, the circuit board 41 is provided on the side of the second surface 10b, the binding strap 42a crosses the circuit board 41 and is attached to two opposite sides of the circuit board 41, the limiter 42b is attached, a part of the limiter 42b is arranged on a side of the backplate assembly 10 beyond the backplate assembly 10, the limiter 42b, the connecting portion 23 and the bending portion 22 participate in defining the second accommodating space S2, as shown in FIG. 20C; and

step S40: forming a second protective structure 52, as shown in FIG. 20D.

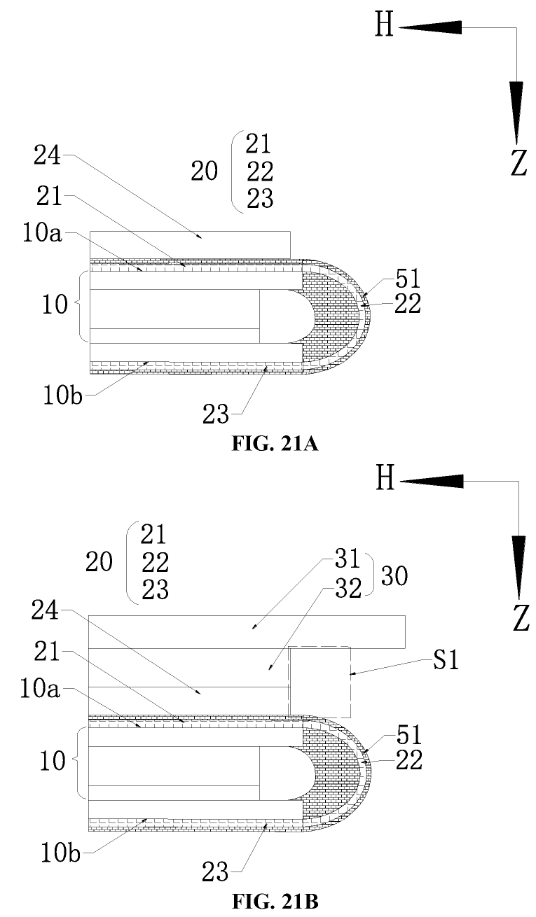

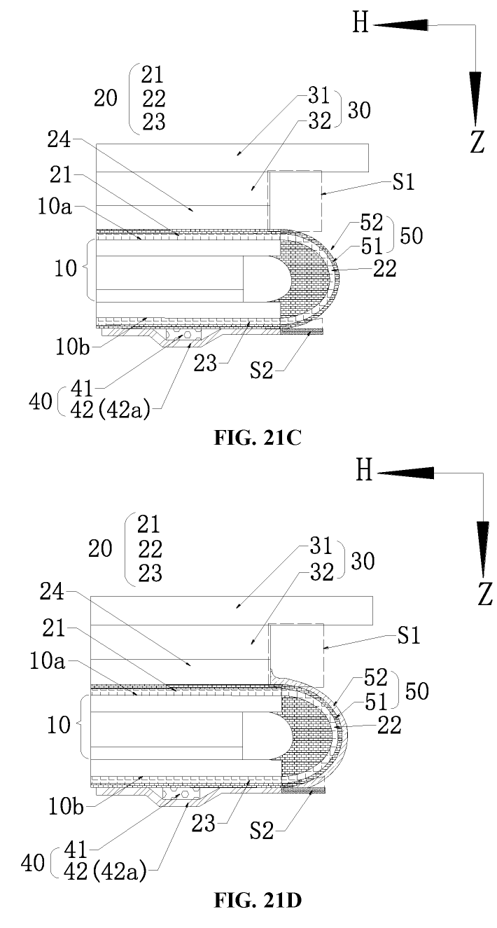

FIGS. 21A to 21D illustrate process steps of a method for preparing a display module 100 according to another embodiment of the second aspect of the present application.

Exemplarily, the method for preparing a display module 100 according to another embodiment of the second aspect of the present application comprises:

step S10: providing a prefabricated module 100’, as shown in FIG. 21A;

step S20: forming a cover plate assembly 30 on the side of the first surface 10a, as shown in FIG. 21B;

step S30: forming, on the side of the second surface 10b, a circuit board assembly 40 electrically connected to the connecting portion 23, where the circuit board assembly 40 comprises a circuit board 41 and a binding member 42, the binding member 42 comprises a binding strap 42a and a limiter 42b, the circuit board 41 is arranged on the side of the second surface 10b, the binding strap 42a crosses the circuit board 41 and is attached to two opposite sides of the circuit board 41, the binding strap 42a is arranged on a side of the backplate assembly 10 beyond the backplate assembly 10, and the binding strap 42a, the connecting portion 23, and the bending portion 22 participate in defining the second accommodating space S2, as shown in FIG. 21C; and

step S40: forming a second protective structure 52, referring to FIG. 21D.

Exemplarily, the material of a part of the binding strap 42a beyond the side of the backplate assembly 10 is glass fiber or polyester fiber, which has high stiffness.

In the above-described embodiment, the binding strap 42a and the limiter 42b in the freely combined binding member 42 can participate in defining the second accommodating space S2, and can be flexibly adjusted according to actual needs.

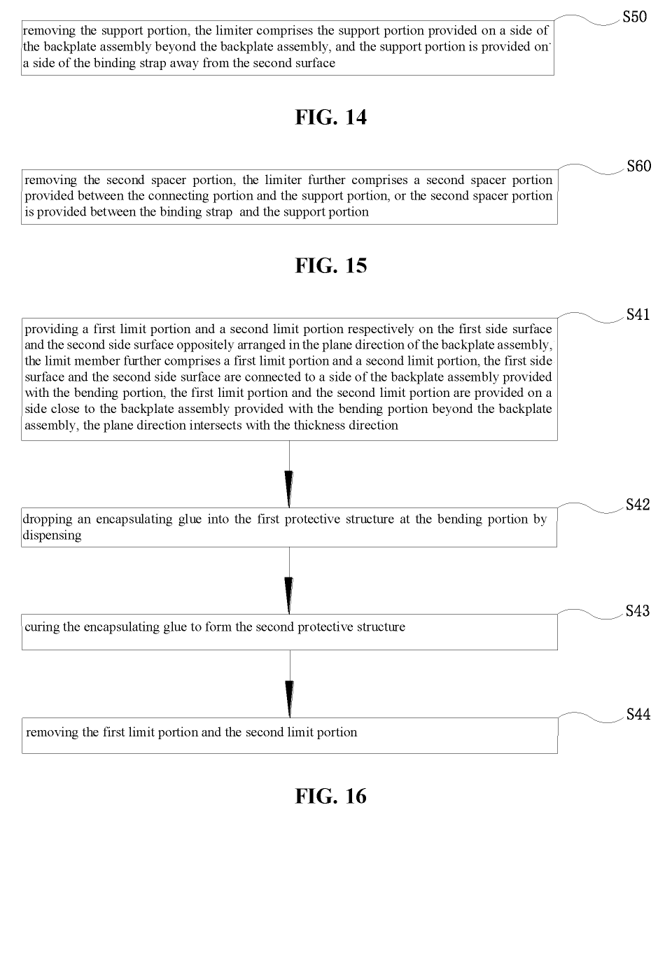

FIG. 14 shows a step flow of a method for preparing a display module 100 according to another embodiment of the second aspect of the present application.

Referring to FIG. 14, in some embodiments, after step S40, the method further comprises:

step S50: removing a support portion 424, the limiter 42b comprises the support portion 424 provided on a side of the backplate assembly 10 beyond the backplate assembly 10, and the support portion 424 is provided on a side of the binding strap 42a away from the second surface 10b.

Exemplarily, the support portion 424 has a dimension of 0.1 to 0.4 mm in the thickness direction Z.

Referring to FIG. 17E, a method for preparing a display module 100 according to an embodiment of the second aspect of the present application further comprises:

step S50: removing a support portion 424, the limiter 42b comprises the support portion 424, the support portion 424 and the binding strap 42a are both provided on a side of the backplate assembly 10 beyond the backplate assembly 10, the support portion 424 is provided on a side of the binding strap 42a away from the second surface 10b, and the support portion 424 plays a role of temporarily enhancing the stiffness of the binding strap 42a.

Referring to FIG. 18E, a method for preparing a display module 100 according to another embodiment of the second aspect of the present application further comprises:

step S50: removing a support portion 424, the limiter 42b comprises the support portion 424 provided on a side of the backplate assembly 10 beyond the backplate assembly 10, the support portion 424 is provided on a side of the binding strap 42a away from the second surface 10b, and the support portion 424 plays a role of temporarily defining the second accommodating space S2.

Referring to FIG. 19E, a method for preparing a display module 100 according to another embodiment of the second aspect of the present application further comprises:

step S50: removing the support portion 424, the limiter 42b comprises the support portion 424, the binding strap 42a and the support portion 424 are both arranged on a side of the backplate assembly 10 beyond the backplate assembly 10, the support portion 424 is arranged on a side of the binding strap 42a away from the second surface 10b, and the support portion 424 plays a role of temporarily defining the second accommodating space S2.

Referring to FIG. 20E, a method for preparing a display module 100 according to another embodiment of the second aspect of the present application further comprises:

step S50: removing the support portion 424, the limiter 42b comprises the support portion 424 arranged on a side of the backplate assembly 10 beyond the backplate assembly 10, the support portion 424 is arranged on a side of the binding strap 42a away from the second surface 10b, and the support portion 424 plays a role of temporarily defining the second accommodating space S2.

In the above embodiment, the support portion 424 can temporarily enhance the stiffness of the binding strap 42a, and assist the binding strap 42a to participate in defining the second accommodating space S2, or the support portion 424 can temporarily participate in defining the second accommodating space S2, and the function of the support portion 424 can be flexibly adjusted according to the actual demand.

FIG. 15 shows a flow chart of a method for preparing a display module 100 according to another embodiment of the second aspect of the present application.

Referring to FIG. 15, in some embodiments, after step S40, the method further comprises:

step S60: removing a second spacer portion 422, the limiter 42b further comprises the second spacer portion 422 provided between the connecting portion 23 and the support portion 424, or the second spacer portion 422 is provided between the binding strap 42a and the support portion 424.

Referring to FIG. 18F, a method for preparing a display module 100 according to an embodiment of the second aspect of the present application further comprises:

step S60: removing a second spacer portion 422, the limiter 42b further comprises the second spacer portion 422 provided between the binding strap 42a and the support 424.

Referring to FIG. 19F, a method for preparing a display module 100 according to another embodiment of the second aspect of the present application further comprises:

step S60: removing a second spacer portion 422, the limiter 42b further comprises the second spacer portion 422 provided between the binding strap 42a and the support 424.

Referring to FIG. 20F, a method for preparing a display module 100 according to an embodiment of the second aspect of the present application further comprises:

step S60: removing a second spacer portion 422, the limiter 42b further comprises the second spacer portion 422 provided between the binding strap 42a and the connecting portion 23.

In the above-described embodiment, the second spacer portion 422 can increase the volume of the second accommodating space S2, increase the error value within the allowable range of the process, which is beneficial to reduce the difficulty and cost of forming the second protective structure 52, while the second spacer portion 422 can further define the dimension of the second protective structure 52 along the thickness direction Z at an end of the second surface 10b, and the shape of the second protective structure 52 can be flexibly adjusted according to actual needs.

In some embodiments, step S40 further comprises:

dropping an encapsulating adhesive into the first protective structure 51 at the bending portion 22 by dispensing, and the encapsulating adhesive flows into the first accommodating space S1 and the second accommodating space S2 toward both sides in the thickness direction Z;

curing the encapsulating adhesive to form a second protective structure 52.

In these embodiments, the formation of the second protective structure 52 adopts a dispensing process to drop the encapsulating adhesive, and the first accommodating space S1 and the second accommodating space S2 are formed on both sides of the first surface 10a and the second surface 10b, respectively, so that the flow direction and position of the encapsulating adhesive can be limited.

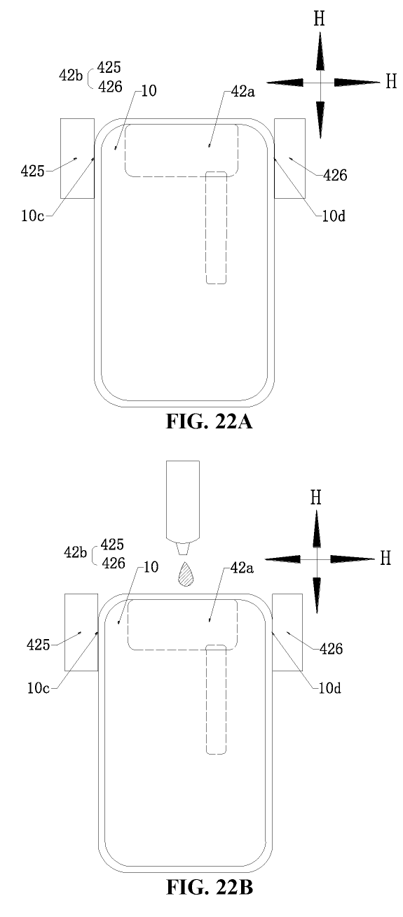

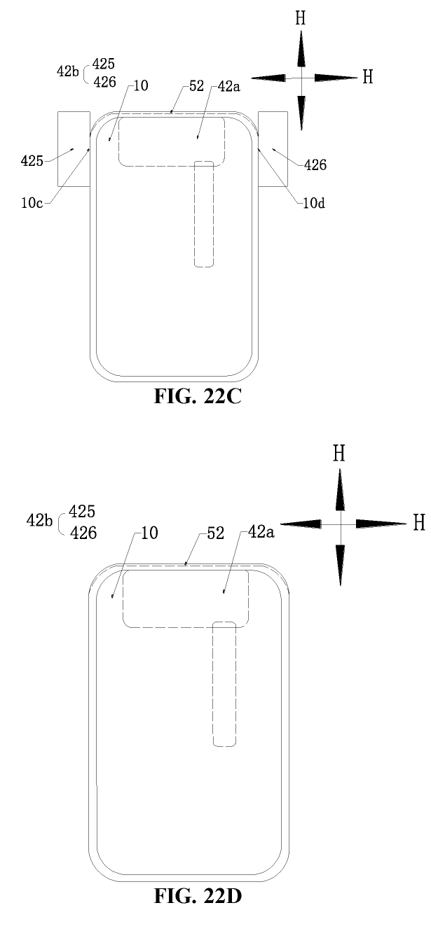

FIG. 16 illustrates a flow chart of a method for preparing a display module 100 according to another embodiment of the second aspect of the present application, and FIGS. 22A to 22D illustrate process steps of a method for preparing a display module 100 according to another embodiment of the second aspect of the present application.

Referring to FIGS. 16 and 22A to 22D, in some embodiments, step S40 further comprises:

step S41: providing a first limit portion 425 and a second limit portion 426 respectively on the first side surface 10c and the second side surface 10d oppositely arranged in the plane direction H of the backplate assembly 10, the limiter 42b further comprises the first limit portion 425 and the second limit portion 426, the first side surface 10c and the second side surface 10d are connected to a side of the backplate assembly 10 provided with the bending portion 22, the first limit portion 425 and the second limit portion 426 are provided on a side close to the backplate assembly 10 provided with the bending portion 22 beyond the backplate assembly 10, the plane direction H is a direction parallel to the plane of the backplate assembly 10 and intersects with the thickness direction Z;

step S42: dropping an encapsulating adhesive into the first protective structure 51 at the bending portion 22 by dispensing;

step S43: curing the encapsulating adhesive to form the second protective structure 52;

step S44: removing the first limit portion 425 and the second limit portion 426.

In these embodiments, in the step of forming the second protective structure 52, it is also necessary to limit the first side surface 10c and the second side surface 10d of the backplate assembly 10, so as to further ensure that when the amount of the encapsulating adhesive is too large, the encapsulating adhesive flows to the positions of the first side surface 10c and the second side surface 10d to achieve effective limit.

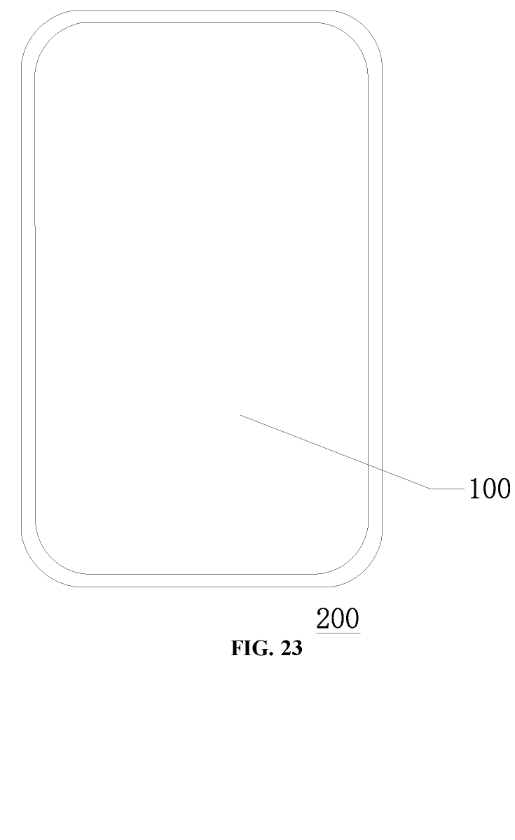

FIG. 23 shows an overall structure of a display device 200 according to an embodiment of the third aspect of the present application.

Referring to FIG. 23, according to the third aspect, embodiments of the present application provide a display device 200 comprising the display module 100 provided by any one of the embodiments of the first aspect of the present application, or comprising the display module 100 prepared by the method for preparing a display module 100 provided by any one of the embodiments of the second aspect of the present application.

In the third aspect, since the display device 200 according to the embodiments of the present application comprises the display module 100 according to any one of the embodiments of the first aspect of the present application, or comprises the display module 100 prepared by the method for preparing the display module 100 according to any one of the embodiments of the second aspect of the present application, the display device 200 according to the embodiments of the third aspect of the present application has the beneficial effects of the display module 100 according to any one of the embodiments of the first aspect of the present application, or the display device 200 according to the embodiments of the third aspect of the present application has the beneficial effects of the method for preparing a display module 100 according to the embodiments of the second aspect of the present application.

The display device 200 in the embodiments of the present application comprises, but is not limited to, a device having a display function, such as a mobile phone, a Personal Digital Assistant (PDA), a tablet computer, an electronic book, a television, an access control, a smart fixed telephone, or a console.

Although the application has been described with reference to preferred embodiments, various modifications may be made thereto and components therein may be replaced with equivalents without departing from the scope of the application. In particular, the technical features mentioned in the various embodiments can be combined in any manner as long as there is no structural conflict. The present application is not limited to the specific embodiments disclosed herein, but comprises all technical solutions falling within the scope of the claims.

What is claimed is:

1. A display module, comprising:
a backplate assembly, comprising a first surface and a second surface arranged oppositely in a thickness direction;
a display panel, comprising a display portion provided on the first surface, a connecting portion provided on the second surface, and a bending portion connecting the display portion and the connecting portion;
a cover plate assembly provided on a side of the first surface, the cover plate assembly comprising a cover plate body and a fixing portion attached to a side of the cover plate body, the cover plate body, the fixing portion, the display portion, and the bending portion participating in defining a first accommodating space;
a circuit board assembly provided on a side of the second surface and electrically connected to the connecting portion; and
a protective assembly comprising a first protective structure and a second protective structure, the first protective structure being located on at least one side of the bending portion away from the backplate assembly, the second protective structure covering the first protective structure, a part of the second protective structure extending to and filling the first accommodating space, and a part of the second protective structure extending to a position where the connecting portion locates.

2. The display module according to claim 1, wherein
the circuit board assembly comprises a circuit board and a binding member arranged on a side of the backplate assembly partially beyond the backplate assembly,
the binding member, the connecting portion and the bending portion participate in defining a second accommodating space, and
the second protective structure extends to and fills the second accommodating space.

3. The display module according to claim 2, wherein
the binding member comprises a binding strap attached to a side of the circuit board away from the second surface, the binding strap extending beyond two opposite sides of the circuit board and being bound and fixed to the connecting portion, the binding strap being arranged on a side of the backplate assembly partially beyond the backplate assembly; and
the binding strap, the connecting portion and the bending portion participate in defining the second accommodating space, and the second protective structure extends and fills the second accommodating space.

4. The display module according to claim 3, wherein
the binding strap further comprises a stiffening section arranged on a side of the backplate assembly beyond the backplate assembly; and
the stiffening section, the connecting portion and the bending portion participate in defining the second accommodating space, and the second protective structure extends and fills the second accommodating space.

5. The display module according to claim 4, wherein the stiffening section comprises a glass fiber material or a polyester fiber material.

6. The display module according to claim 4, wherein the binding member further comprises a first spacer portion arranged between the stiffening section and the connecting section; the connecting section, the stiffening section, the first spacer portion and the bending section participate in defining the second accommodating space; and the second protective structure extends and fills the second accommodating space; or
the binding member further comprises a first spacer portion arranged between the binding strap and the connecting portion; the connecting portion, the binding strap, the first spacer portion, and the bending portion participate in defining the second accommodating space; and the second protective structure extends and fills the second accommodating space.

7. The display module according to claim 6, wherein a dimension of the first spacer portion in the thickness direction is consistent with a dimension of an end of the second protective structure extending to the second accommodating space in the thickness direction.

8. The display module according to claim 6, wherein the first spacer portion comprises a foam material.

9. The display module according to claim 4, wherein a direction parallel to a plane of the backplate assembly is a plane direction that intersects with the thickness direction, and a first preset distance is set between the stiffening section or the binding strap and an arc top of the bending portion along the plane direction.

10. The display module according to claim 1, wherein
the circuit board assembly comprises a circuit board and a binding member, the binding member comprising a binding strap attached to a side of the circuit board away from the second surface, the binding strap extending beyond two opposite sides of the circuit board and being bound and fixed to the connecting portion;
a direction parallel to a plane of the backplate assembly is a plane direction that intersects with the thickness direction, and
the second protective structure extends to an end of the binding strap close to the bending portion, and a second preset distance is set between the second protective structure and the binding strap, or
the second protective structure extends to and covers the end of the binding strap close to the bending portion, and a third preset distance is set between the end of the binding strap close to the bending portion and the connecting portion in the plane direction intersecting with the thickness direction.

11. The display module according to claim 10, wherein the second preset distance or the third preset distance is 0, and the second protective structure abuts against the binding strap.

12. The display module according to claim 1, wherein the second protective structure extends along the display portion to a side of the fixing portion close to the display portion in the first accommodating space.

13. The display module according to claim 12, wherein the second protective structure extends in the first accommodating space and covers at least part of a side portion of the fixing portion.

14. A method for preparing a display module, comprising:
providing a prefabricated module comprising a backplate assembly, a display panel and a connecting portion, wherein
the display panel comprises a display portion, a bending portion, and a first protective structure,
the backplate assembly comprises a first surface and a second surface arranged oppositely in a thickness direction,
the first protective structure covers a side of the display panel away from the backplate assembly, and
the display portion is arranged on the first surface, the connecting portion is arranged on the second surface, and the bending portion is bent on a side of the backplate assembly to connect the display portion and the connecting portion;
forming, on a side of the first surface, a cover plate assembly that comprises a cover plate body and a fixing portion, and sequentially attaching the fixing portion and the cover body on the side of the first surface, wherein the cover body, the fixing portion, the display portion, and the bending portion participate in defining a first accommodating space;
forming, on a side of the second surface, a circuit board assembly electrically connected to the connecting portion, wherein
the circuit board assembly comprises a circuit board and a binding member, the binding member comprising a binding strap and a limiter,
the circuit board is provided on a side of the second surface,
the binding strap is arranged across the circuit board and is attached to two opposite sides of the circuit board, and
the limiter is attached,
a part of the binding member is arranged on a side of the backplate assembly beyond the backplate assembly, and the part of the binding member, the connecting portion and the bending portion participate in defining a second accommodating space; and
forming a second protective structure in the first accommodating space, on the first protective structure, and in the second accommodating space, wherein the second protective structure partially fills the second accommodating space and extends to a position where the connecting portion locates.

15. The method for preparing a display module according to claim 14, wherein
the limiter comprises a support portion, and support portion is arranged on a side of the backplate assembly beyond the backplate assembly and is arranged on a side of the binding strap away from the second surface, and
after the forming a second protective structure, the method further comprises:
removing the support portion.

16. The method for preparing a display module according to claim 15, wherein
the limiter further comprises a second spacer portion, and the second spacer portion is arranged between the connecting portion and the support portion, or arranged between the binding strap and the support portion, and
after the forming a second protective structure, the method further comprises:
removing the second spacer portion.

17. The method for preparing a display module according to claim 14, wherein the forming a second protective structure further comprises:
dropping an encapsulating adhesive into the first protective structure at the bending portion by dispensing, so as to make the encapsulating glue flow along the thickness direction toward two sides into the first accommodating space and the second accommodating space; and
curing the encapsulating adhesive to form the second protective structure.

18. The method for preparing a display module according to claim 14, wherein
the limiter further comprises the first limit portion and the second limit portion, and
the forming a second protective structure further comprises:
providing the first limit portion and the second limit portion respectively on a first side surface and a second side surface of the backplate assembly oppositely arranged in a plane direction that is a direction parallel to a plane of the backplate assembly, and the plane direction intersects with the thickness direction, wherein
the first side surface and the second surface are connected to a side of the backplate assembly provided with the bending portion, and
the first limit portion and the second limit portion are arranged beyond the backplate assembly at sides thereof that are close to the side of the backplate assembly provided with the bending portion;
dropping an encapsulating adhesive into the first protective structure at the bending portion by dispensing;
curing the encapsulating adhesive to form the second protective structure; and
removing the first limit portion and the second limit portion.

19. A display device, wherein the display device comprises the display module, comprising:
a backplate assembly, comprising a first surface and a second surface arranged oppositely in a thickness direction;
a display panel, comprising a display portion provided on the first surface, a connecting portion provided on the second surface, and a bending portion connecting the display portion and the connecting portion;
a cover plate assembly provided on a side of the first surface, the cover plate assembly comprising a cover plate body and a fixing portion attached to a side of the cover plate body, the cover plate body, the fixing portion, the display portion, and the bending portion participating in defining a first accommodating space;
a circuit board assembly provided on a side of the second surface and electrically connected to the connecting portion; and
a protective assembly comprising a first protective structure and a second protective structure, the first protective structure being located on at least one side of the bending portion away from the backplate assembly, the second protective structure covering the first protective structure, a part of the second protective structure extending to and filling the first accommodating space, and a part of the second protective structure extending to a position where the connecting portion locates;
or the display device comprises the display module prepared by the method for preparing a display module, comprising:
providing a prefabricated module comprising a backplate assembly, a display panel and a connecting portion, wherein
the display panel comprises a display portion, a bending portion, and a first protective structure,
the backplate assembly comprises a first surface and a second surface arranged oppositely in a thickness direction,
the first protective structure covers a side of the display panel away from the backplate assembly, and
the display portion is arranged on the first surface, the connecting portion is arranged on the second surface, and the bending portion is bent on a side of the backplate assembly to connect the display portion and the connecting portion;
forming, on a side of the first surface, a cover plate assembly that comprises a cover plate body and a fixing portion, and sequentially attaching the fixing portion and the cover body on the side of the first surface, wherein the cover body, the fixing portion, the display portion, and the bending portion participate in defining a first accommodating space;
forming, on a side of the second surface, a circuit board assembly electrically connected to the connecting portion, wherein
the circuit board assembly comprises a circuit board and a binding member, the binding member comprising a binding strap and a limiter,
the circuit board is provided on a side of the second surface,
the binding strap is arranged across the circuit board and is attached to two opposite sides of the circuit board, and
the limiter is attached,
a part of the binding member is arranged on a side of the backplate assembly beyond the backplate assembly, and the part of the binding member, the connecting portion and the bending portion participate in defining a second accommodating space; and
forming a second protective structure in the first accommodating space, on the first protective structure, and in the second accommodating space, wherein the second protective structure partially fills the second accommodating space and extends to a position where the connecting portion locates.
